(19) United States
(12) Patent Application Publication
(10) Pub. No.: US 2021/0328598 A1
(43) Pub. Date: Oct. 21, 2021

(54) Correction of Errors in Soft Demodulated Symbols Using a CRC

(71) Applicant: Google LLC, Mountain View, CA (US)

(72) Inventor: Venu Madhav Annamraju, Hyderabad, Telangana (IN)

(21) Appl. No.: 16/964,835

(22) PCT Filed: Dec. 14, 2018
(86) PCT No.: PCT/US2018/065868

§ 371 Date: Jul. 24, 2020

(51) Int. Cl. H03M 13/09; H03M 13/00; H03M 13/45; H03M 13/43

(52) U.S. Cl. CPC H03M 13/09; H03M 13/43; H03M 13/45; H03M 13/6325

(57) ABSTRACT

The system and method described provide correction of modulation symbol errors which may occur during audio pairing of computing devices. The transmission between the computing devices comprises a six modulation symbol (24 bit) token containing transaction information and a two check symbol (8 bit) cyclic redundancy check (“CRC”). Error probabilities of symbols are be used to identify probable symbol error locations and the number of errors contained in the received transmission during the symbol decoding process. If there is a single modulation symbol error, the 16 possible combinations of bit values are cycled through until one combination passes the CRC check. If there are two modulation symbol errors, the 256 possible combinations of bit values are cycled through until two combinations pass the CRC check.

### TECHNICAL FIELD

The example embodiments described herein provide for correction of symbol errors, which may occur during audio pairing of computing devices, using error probabilities to identify the probable locations of the symbol errors.

### BACKGROUND

Computing devices have speakers that emit data via audio communications. Audio communications can be used to pair multiple computing devices to transmit data between the devices, wherein the data may be transmitted as a token. A transaction is a successful transfer of data. Audio based pairing can be utilized to establish communication between two devices, such as email or short message service (“SMS”), or in various other applications where secure internet or wireless access may not be available, e.g., payment applications.

When tokens are transmitted by audio channels, the tokens may become corrupted during the transmission process and therefore received by the computing device containing errors. The token corruption may occur due to the two devices being at the threshold of the operating radius, and/or noise in the near ultrasound band caused by speech harmonics, environmental noise, interference from other broadcasters, or other sources. If the errors cannot be corrected, the token must be discarded. Transmission of tokens between the users must continue until a valid token is received to conduct the transaction.

The correction of any such errors without transmitting additional data will reduce the transmission failure rate and improve resilience to noise during the transmission process.

### SUMMARY

Techniques herein provide computer-implemented methods to correct a single modulation symbol error received during audio pairing of computing devices. In an example, a computing device receives an audio transmission, wherein the audio transmission comprises audio token data and a check value. The audio token data comprises one or more modulation symbols and the check value comprises a cyclic redundancy check (“CRC”) comprised of two check symbols. The computing device decodes the modulation and check symbols and calculates an audio token data check value. The computing device determines that the calculated audio token data check value does not match the received check value. The computing device then determines an error probability for each decoded modulation symbol and compares the error probability for each decoded modulation symbol with a threshold. The computing device determines that the audio token data has a single symbol error, wherein a symbol error occurs at a decoded modulation symbol location where the error probability is less than the threshold. In response to determining that a single symbol error has occurred, the computing device modifies the decoded modulation symbol at the decoded modulation symbol location comprised of the single symbol error and recalculates the audio token check value.

For a single symbol error, wherein a symbol is composed of four bits and a bit has two possible values either 0 or 1, the modification process cycles through up to 16 combinations (i.e., 2⁴=16) of bit configurations to determine which configuration passes the CRC by matching the calculated audio token data check value with the received check value. In an example, to correct two symbol errors, which would be comprised of eight bits, using error probabilities to identify the probable locations of the symbol errors, the modification process cycles through up to 256 combinations (i.e., 2⁸=256) of bit configurations to determine which configuration passes the CRC.

The computing device compares the recalculated audio token check value with the received check value and accepts the audio token data when the recalculated audio token check value matches the received check value.

In certain other example aspects described herein, systems and computer program products to correct a single modulation symbol error received during audio pairing of computing devices are provided.

These and other aspects, objects, features, and advantages of the examples will become apparent to those having ordinary skill in the art upon consideration of the following detailed description of illustrated examples.

### BRIEF DESCRIPTION OF THE DRAWINGS

FIG. 1 is a block diagram depicting a system for a single modulation symbol error correction or two modulation symbol error correction using cyclic redundancy check (“CRC”), in accordance with certain example embodiments.

FIG. 2 is a block flow diagram depicting a method to pair computing devices to process a transaction, in accordance with certain example embodiments.

FIG. 3 is a block flow diagram depicting a method to decode an audio token to determine the location and the number of modulation symbol errors, in accordance with certain example embodiments.

FIG. 4 is a block flow diagram depicting a method to correct a single modulation symbol error using CRC, in accordance with certain example embodiments.

FIG. 5 is a block flow diagram depicting a method to correct one or two modulation symbol errors using CRC, in accordance with certain example embodiments.

FIG. 6 is a block flow diagram depicting a method to verify a token based on a transaction identifier and location proximity, in accordance with certain example embodiments.

FIG. 7 is a block diagram depicting a computing machine and module, in accordance with certain example embodiments.

### DETAILED DESCRIPTION OF EXAMPLE EMBODIMENTS

### Overview

The example embodiments described herein provide correction of modulation symbol errors which may occur during audio pairing of computing devices. In an example, audio based pairing of computing devices may be used to transfer data between computing devices. In an example, audio pair of computing devices may be used to conduct payment transactions through payment applications installed on user computing devices.

In an example, each user computing device installs an audio based payment application to send or receive transaction information. To conduct a payment transaction, the user wishing to send the payment must correspondingly control a user interface of the sending computing device such as pressing a pay button. At the same time, the user that is to receive the payment must correspondingly control a user interface of the receiving computing device, such as by pressing a receive interface object. The transmission between the devices is comprised of a 24 bit token and an 8 bit cyclic redundancy check (“CRC”). Each set of four bits composes a symbol. Therefore, in the example the token is composed of six modulation symbols and the CRC is composed of two check symbols.

In an example, the token must be received with integrity for the transaction to be processed. Due to error sources during the transmission, the token may become corrupted. If the CRC is incapable of correcting the transmitted data, the token must be discarded. The transmission between the two user computing devices will be repeated until a valid token is received.

In an example, error probabilities of modulation symbols may be used to identify probable modulation symbol locations where errors may have occurred and the number of errors contained in the received modulation symbols during the modulation symbol decoding process. During the decoding process, a confidence score (i.e., error probability) may be calculated for each modulation symbol indicating whether the modulation symbol has been correctly decoded by the receiving user computing device. In an example, a confidence score of 1.0 indicates that the modulation symbol was decoded correctly. A confidence score between a configured threshold and 1.0 may indicate that some corruption is present in the modulation symbol and a confidence score less than a configured threshold may indicate that the modulation symbol is incorrect. The configured threshold may be 0.3, 0.4, 0.5, or any other suitable threshold value.

In an example, if it is determined that there is only a single modulation symbol error and the location is predicted based upon the confidence score of the modulation symbol, 16 possible combinations of bits may be cycled through until one combination passes the CRC check. In an example, if it is determined that there are two modulation symbol errors and the locations are predicted based upon the confidence scores of the modulation symbols, 256 possible combinations of bits may be cycled through until one combination passes the CRC check.

In an example, if a CRC symbol is determined to be corrupted, a CRC re-calculation with decoded symbols yields another CRC symbol.

In an example, if the modulation symbol location and/or the error count are incorrect, cycling the received symbols will cause the CRC check to fail.

In an example, if more than one modulation symbol passes the CRC check while cycling through the modulation symbols at the modulation symbol location, then all of the modulation symbols should be discarded or checked at the server for validity depending on an acceptable threshold of false hits.

### Example System Architecture

Turning now to the drawings, in which like numerals indicate like (but not necessarily identical) elements throughout the figures, example embodiments are described in detail.

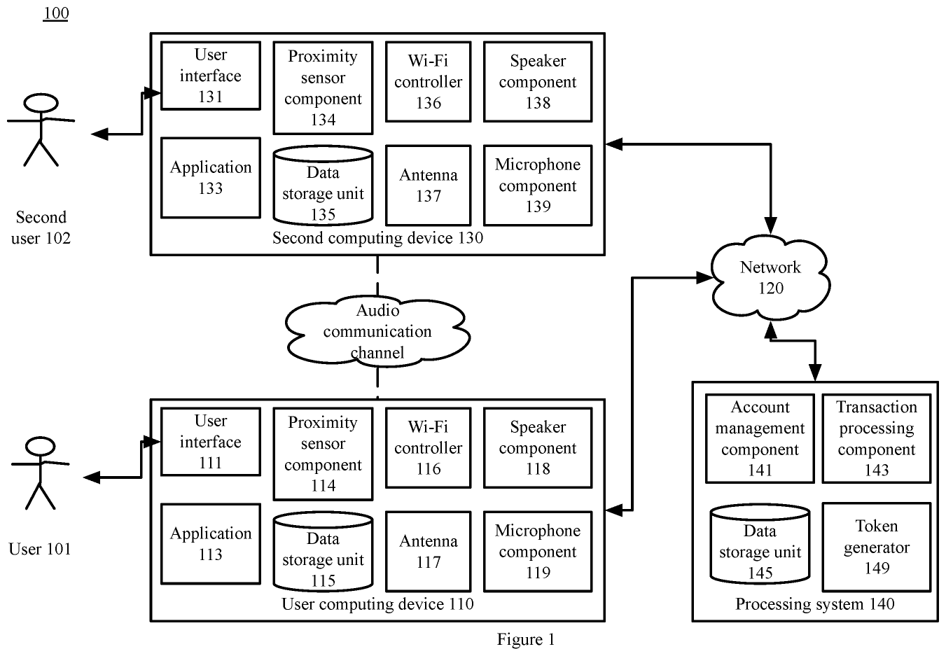

FIG. 1 is a block diagram depicting a system 100 for pairing a user computing device 110 with a second computing device 130 via proximity sensing and audio communication to conduct a transaction, in accordance with certain example embodiments. As depicted in FIG. 1, the system 100 includes network computing devices 110, 130, and 140 that are configured to communicate with one another via one or more networks 120. In some embodiments, a user associated with a device must install an application and/or make a feature selection to obtain the benefits of the techniques described herein.

In example embodiments, the network 120 can include a local area network (“LAN”), a wide area network (“WAN”), an intranet, an Internet, storage area network (“SAN”), personal area network (“PAN”), a metropolitan area network (“MAN”), a wireless local area network (“WLAN”), a virtual private network (“VPN”), a cellular or other mobile communication network, Bluetooth, Bluetooth low energy (“BLE”), near field communication (“NFC”), ultrasound communication, or any combination thereof or any other appropriate architecture or system that facilitates the communication of signals, data, and/or messages. Throughout the discussion of example embodiments, it should be understood that the terms “data” and “information” are used interchangeably herein to refer to text, images, audio, video, or any other form of information that can exist in a computer-based environment.

Each network computing device 110, 130, and 140 includes a device having a communication module capable of transmitting and receiving data over the network 120. For example, each network computing device 110, 130, and 140 can include a server, desktop computer, laptop computer, tablet computer, a television with one or more processors embedded therein and/or coupled thereto, smart phone, handheld computer, personal digital assistant (“PDA”), or any other wired or wireless, processor-driven device. In the example embodiment depicted in FIG. 1, the network computing devices 110, 130, and 140 are operated by user 101, second user 102, and processing system 140 operators, respectively.

In certain embodiments, two computing devices comprising a user computing device 110 and a second computing device 130 are paired via proximity sensing in response to a tap of the two devices.

An example user computing device 110 comprises a user interface 111, an application 113, a proximity sensor component 114, a data storage unit 115, a Wi-Fi controller 116, an antenna 117, a speaker component 118, and a microphone component 119.

In an example embodiment, the user interface 111 enables the user 101 to interact with the user computing device 110. For example, the user interface 111 may be a touch screen, a voice-based interface, or any other interface that allows the user 101 to provide input and receive output from an application on the user computing device 110. In an example embodiment, the user 101 interacts via the user interface 111 with the application 113.

In an example embodiment, the application 113 is a program, function, routine, applet, or similar entity that exists on and performs its operations on the user computing device 110. In certain example embodiments, the user 101 must install the application 113 and/or make a feature selection on the user computing device 110 to obtain the benefits of the techniques described herein. In an example embodiment, the user 101 may access the application 113 on the user computing device 110 via the user interface 111. In an example embodiment, the application 113 may be associated with the processing system 140. In an example embodiment, the application 113 comprises a merchant application, an Internet browser, a digital wallet application, a loyalty card application, another value-added application, a user interface 111 application, or other suitable application operating on the second computing device 110.

In an example embodiment, the proximity sensor component 114 comprises a proximity sensor device capable of detecting objects within a predefined proximity of the proximity sensor device. In an example, the proximity sensor component 114 comprises an infrared proximity sensor. In an example embodiment, the proximity sensor component 114 communicates with the application 113, for example, the proximity sensor component 114 transmits an alert to the application 113 in response to detecting an object. In another example embodiment, the proximity sensor component 114 transmits instructions to open the application 113 in response to detecting an object.

In an example embodiment, the data storage unit 115 comprises a local or remote data storage structure accessible to the user computing device 110 suitable for storing information. In an example embodiment, the data storage unit 115 stores encrypted information, such as HTML5 local storage.

In an example embodiment, the Wi-Fi controller 116 is capable of sending and receiving data, performing authentication and ciphering functions, and directing how the user computing device 110 will listen for transmissions from the second computing device 130 or configuring the user computing device 110 into various power-save modes according to Wi-Fi-specified procedures. In another example embodiment, the user computing device 110 comprises a Bluetooth controller, Bluetooth low energy (“BLE”) controller, or an NFC controller capable of performing similar functions. An example Wi-Fi controller 116 communicates with the application 113 and is capable of sending and receiving data over a wireless, Wi-Fi communication channel. In another example embodiment, a Bluetooth controller, BLE controller, or NFC controller performs similar functions as the Wi-Fi controller 116 using Bluetooth, BLE, or NFC protocols. In an example embodiment, the Wi-Fi controller 116 activates the antenna 117 to create a wireless communication channel between the user computing device 110 and the second computing device 130. For example, the user computing device 110 communicates with the second computing device 130 via the antenna 117. In an example embodiment, when the user computing device 110 has been activated, the Wi-Fi controller 116 polls through the antenna 117 an audio signal, or listens for audio signals from the second computing device 130.

In an example embodiment, the antenna 117 is a means of communication between the user computing device 110 and the second computing device 130. In an example embodiment, a Wi-Fi controller 116 outputs through the antenna 117 an audio signal, or listens for audio signals from the second computing device 130. In another example embodiment a Bluetooth controller or a near field communication (“NFC”) controller is used.

In an example embodiment, the speaker component 118 comprises a speaker device or other device capable of producing an ultrasound output. In an example embodiment, the speaker component 118 can communicate with the application 113 to receive an instruction to broadcast an ultrasound output. In an example embodiment, the speaker component 118 is a component of the user computing device 110. In another example embodiment, the speaker component 118 is communicatively coupled to the user computing device 110.

In an example embodiment, the microphone component 119 comprises a microphone device that is capable of receiving sound inputs from an environment of the user computing device 110. In an example embodiment, the sound inputs are ultrasound inputs. In an example embodiment, the microphone component 119 communicates with the application 113 to receive an instruction to transition from a passive mode to an active mode and listen for sound inputs. In an example embodiment, the microphone component 119 receives sound inputs while in the active mode and transmits the received sound inputs to the application 113.

An example second computing device 130 comprises a user interface 131, an application 133, a proximity sensor component 134, a data storage unit 135, a Wi-Fi controller 136, an antenna 137, a speaker component 138, and a microphone component 139. In an example embodiment, the second computing device 130 comprises a mobile computing device such as a smartphone device, tablet device, or other mobile computing device. In another example embodiment, the second computing device 130 comprises a point of sale terminal.

In an example embodiment, the user interface 131 enables the second user 102 to interact with the second computing device 130. For example, the user interface 131 may be a touch screen, a voice-based interface, or any other interface that allows the second user 102 to provide input and receive output from an application on the second computing device 130. In an example embodiment, the second user 102 interacts via the user interface 131 with the application 133.

In an example embodiment, the application 133 is a program, function, routine, applet, or similar entity that exists on and performs its operations on the second computing device 130. In certain example embodiments, the second user 102 must install the application 133 and/or make a feature selection on the second computing device 130 to obtain the benefits of the techniques described herein. In an example embodiment, the second user 102 may access the application 133 on the second computing device 130 via the user interface 131. In an example embodiment, the application 133 may be associated with the processing system 140. In an example embodiment, the application 133 comprises a merchant application, an Internet browser, a digital wallet application, a loyalty card application, another value-added application, a user interface 131 application, or other suitable application operating on the second computing device 130.

In an example embodiment, the proximity sensor component 134 comprises a proximity sensor device capable of detecting objects within a predefined proximity of the proximity sensor device. In an example, the proximity sensor component 134 comprises an infrared proximity sensor. In an example embodiment, the proximity sensor component 134 communicates with the application 133, for example, the proximity sensor component 134 transmits an alert to the application 133 in response to detecting an object. In certain other example embodiments, the second computing device 130 does not comprise a proximity sensor component 134.

In an example embodiment, the data storage unit 135 comprises a local or remote data storage structure accessible to the second computing device 130 suitable for storing information. In an example embodiment, the data storage unit 135 stores encrypted information, such as HTML5 local storage.

In an example embodiment, the Wi-Fi controller 136 is capable of sending and receiving data, performing authentication and ciphering functions, and directing how the second computing device 130 will listen for transmissions from the user computing device 110 or configuring the second computing device 130 into various power-save modes according to Wi-Fi-specified procedures. In another example embodiment, the second computing device 130 comprises a Bluetooth controller, Bluetooth low energy (“BLE”) controller, or an NFC controller capable of performing similar functions. An example Wi-Fi controller 136 communicates with the application 133 and is capable of sending and receiving data over a wireless, Wi-Fi communication channel. In another example embodiment, a Bluetooth controller, BLE controller, or NFC controller performs similar functions as the Wi-Fi controller 136 using Bluetooth, BLE, or NFC protocols. In an example embodiment, the Wi-Fi controller 136 activates the antenna 137 to create a wireless communication channel between the second computing device 130 and the user computing device 110. For example, the second computing device 130 communicates with the user computing device 110 via the antenna 137. In an example embodiment, when the second computing device 130 has been activated, the Wi-Fi controller 136 polls through the antenna 137 an audio signal, or listens for audio signals from the user computing device 110.

In an example embodiment, the antenna 137 is a means of communication between the second computing device 130 and the user computing device 110. In an example embodiment, a Wi-Fi controller 136 outputs through the antenna 137 a radio signal, or listens for radio signals from the user computing device 110. In another example embodiment a Bluetooth controller or a near field communication (“NFC”) controller is used.

In an example embodiment, the speaker component 138 comprises a speaker device or other device capable of producing an ultrasound output. In an example embodiment, the speaker component 138 can communicate with the application 133 to receive an instruction to broadcast an ultrasound output. In an example embodiment, the speaker component 138 is a component of the second computing device 130. In another example embodiment, the speaker component 138 is communicatively coupled to the second computing device 130.

In an example embodiment, the microphone component 139 comprises a microphone device that is capable of receiving sound inputs from an environment of the second computing device 130. In an example embodiment, the microphone component 139 communicates with the application 133 to receive an instruction to transition from a passive mode to an active mode and listen for sound inputs. In an example embodiment, the microphone component 139 receives sound inputs while in the active mode and transmits the received sound inputs to the application 133.

An example processing system 140, or service processing system, comprises an account management component 141, a transaction processing component 143, a data storage unit 145, and a token generator 149.

In an example embodiment, the account management component 141 manages user 101 accounts and second user 102 accounts associated with users 101 and second users 102, respectively. The account management component 141 may receive requests to add, edit, delete, or otherwise modify account information for a user 101 account or a second user 102 account.

In an example embodiment, the transaction processing component 143 receives transaction details from a second computing device 130 and information associated with a user 101 account. An example transaction authorization request may comprise second user 102 account information, user 101 account information, and transaction details.

In another example embodiment, the transaction processing component 143 receives a transaction identifier generated by the second computing device 130, a second computing device 130 identifier, and transaction details from the second computing device 130. In an example embodiment, the transaction processing component 143 identifies a second user system account based on the second computing device 130 identifier and identifies a second user system account associated with the second user system account for use in the transaction. In an example embodiment, the transaction processing component 143 associates the received transaction details, transaction identifier and second user system account information and stores the associated transaction details, transaction identifier, and second user system account information in a data storage unit 145 or other memory accessible by the processing system 140.

In an example embodiment, the data storage unit 145 comprises a local or remote data storage structure accessible to the processing system 140 suitable for storing information. In an example embodiment, the data storage unit 145 stores encrypted information, such as HTML5 local storage.

In an example embodiment, the transaction processing component 143 receives the transaction identifier from the user computing device 110. In this example embodiment, the transaction processing component 143 extracts the stored transaction details and second user system account information associated with the transaction identifier. In an example embodiment, the transaction processing component 143 receives a user 101 account identifier based on a selection of the user 101 of the particular account via the user interface 111 of the user computing device 110. In this example embodiment, the transaction processing component 143 extracts the user 101 account information associated with the payment account identifier.

In an example embodiment, the transaction processing component 143 transmits the received transaction identifier generated by the second computing device 130, the second computing device 130 identifier, and transaction details from the second computing device 130 to the token generator 149. The token generator 149 generates a 24 bit token and an 8 bit cyclic redundancy check (“CRC”) to be transmitted to application 133 of the second computing device 130.

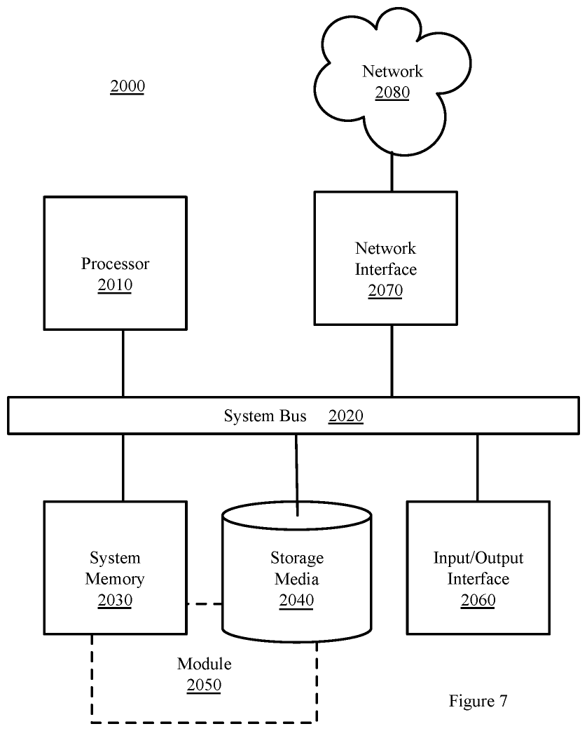

In example embodiments, the network computing devices and any other computing machines associated with the technology presented herein may be any type of computing machine such as, but not limited to, those discussed in more detail with respect to FIG. 7. Furthermore, any functions, applications, or components associated with any of these computing machines, such as those described herein or any others (for example, scripts, web content, software, firmware, hardware, or modules) associated with the technology presented herein may by any of the components discussed in more detail with respect to FIG. 7. The computing machines discussed herein may communicate with one another, as well as with other computing machines or communication systems over one or more networks, such as network 120. The network 120 may include any type of data or communications network, including any of the network technology discussed with respect to FIG. 7.

### Example Processes

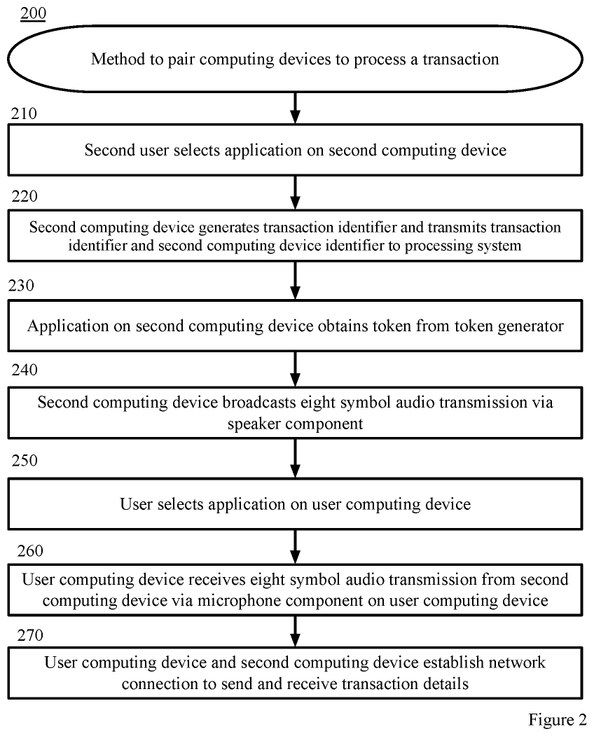

The example methods illustrated in FIGS. 2-6 are described hereinafter with respect to the components of the example operating environment 100. The example methods of FIGS. 2-6 may also be performed with other systems and in other suitable environments. The operations described with respect to any of the FIGS. 2-6 can be implemented as executable code stored on a computer or machine readable non-transitory storage medium (e.g. floppy disk, hard disk, ROM, EEPROM, nonvolatile RAM, CD-ROM, etc.) that are completed based on execution of the code by a processor circuit implemented as executable logic that is encoded in one or more non-transitory media for execution (e.g., programmable logic arrays or devices, field programmable gate arrays, programmable array logic, application specific integrated circuits, etc.).

FIG. 2 is a block flow diagram depicting a method 200 to pair user computing device 110 with a second computing device 130 computing device via proximity sensing and audio communication to conduct a transaction, in accordance with certain example embodiments. The method 200 is described with reference to the components illustrated in FIG. 1.

In block 210, the second user 102 selects the application 133 on the second computing device 130 to initiate a transaction. In an example, a transaction may be a communication between two computing devices wherein data is transferred from a first computing device to a second computing device including email, SMS messaging, financial transactions, check-ins, authorizations, authentications for entry, ticket validations, or any other suitable data transfer. In an example, in response to receiving a verbal request from the user 101 to select the application 133 as a transaction option, the second user 102 actuates an object on the user interface 131 of the second computing device 130 corresponding to the application 133.

In block 220, the second computing device 130 generates a transaction identifier. The second computing device 130 transmits the transaction identifier, transaction details, and a second computing device 130 identifier to the processing system 140. In an example, the transaction identifier comprises a string of alphanumeric and/or symbolic characters. In an example, the transaction details may comprise details of a message, such as an email, SMS messaging, or other suitable messaging options. In an example, the transaction details may comprise details of a financial transaction such as a total amount for the transaction, and/or a listing of one or more items purchased by user 101. In an example, the transaction details may comprise details of a user check-in such as at a hotel, a transportation hub, a conference, a security check-in, or other suitable check-in option. In an example, the transaction details may comprise details of an authorization, an authentication for entry, or a ticket validation. In an example, the second computing device 130 identifier comprises a media access control (“MAC”) address, hardware identifier, or other identifier associated with the second computing device 130. In an example, the second computing device 130 transmits the transaction identifier to the processing system 140 via the network 120.

In block 230, application 133 receives a transmission from the token generator 149 comprised of a 24 bit token and an 8 bit CRC. In an example, the 24 bit token is comprised of the transaction identifier which is transmitted as six modulation symbols designated as d₁, d₂, d₃, d₄, d₅, and d₆, wherein each modulation symbol is comprised of four bits. In an example, the CRC is comprised of two check symbols designated as c₁ and c₂, wherein each check symbol is comprised of four bits.

In block 240, the second computing device 130 broadcasts an eight symbol transmission comprised of the six modulation symbol token and the two check symbol CRC via the speaker component 138 of the second computing device 130. In an example, the second computing device 130 transmits the token and the CRC for a predetermined period of time, for example, for 30 seconds, one minute, 3 minutes, or other suitable predetermined period of time. In an example, the second computing device 130 broadcasts the token and the CRC via an ultrasound communication or an audible communication channel.

In block 250, the user 101 selects application 113 on the user computing device 110. For example, the user 101 actuates an interface object on the user interface display to select application 113. In block 260, the user computing device 110 activates a microphone component 119 and receives the eight symbol audio transmission comprised of the six modulation symbol token and the two check symbol CRC broadcast by the second computing device 130.

In block 270, after receipt of the eight symbol transmission, the user computing device 110 and the second computing device 130 establish a connection via network 120 to send and receive transaction details.

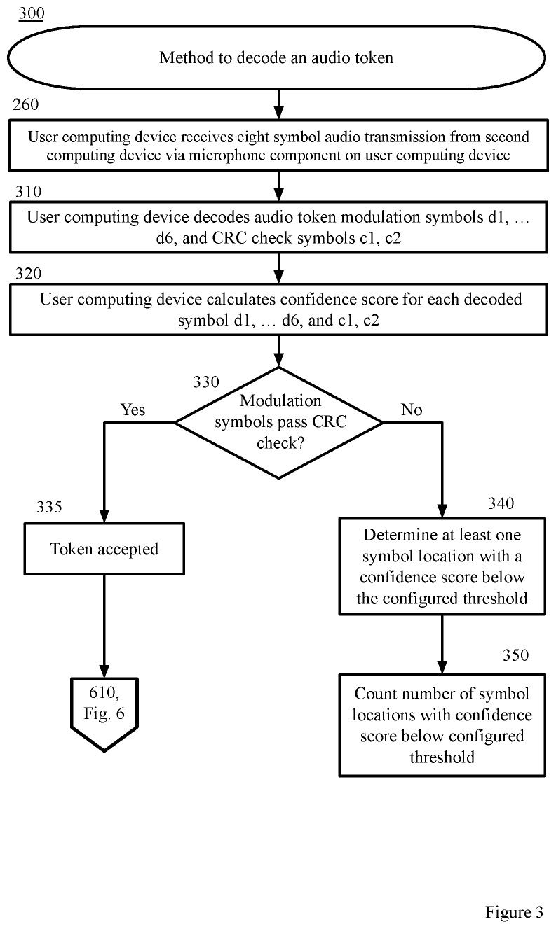

FIG. 3 is a block flow diagram depicting a method 300 to decode an audio token by the user computing device 110 using the CRC, in accordance with certain example embodiments. The method 300 is described with reference to the components illustrated in FIG. 1.

Referring back to block 260, the user computing device 110 activates a microphone component 119 and receives an eight symbol audio transmission comprised of the six modulation symbol token and the two check symbol CRC broadcast by the second computing device 130, as described in greater detail with respect to FIG. 2.

In block 310, the user computing device 110 decodes each of the six modulation symbols contained in the token, wherein the modulation symbols are designated as d₁, . . . dₙ, . . . , d₆, and the two CRC check symbols designated as c₁ and c₂. In an example, decoding each of the modulation symbols and check symbols translates the symbols into bit notation. In an example, in bit notation, each bit has a decoded value of 0 or 1.

The following table illustrates an example of decoded modulation symbol dₙ.

Example Decoded Modulation Symbol dₙ

| Bit Designation | Example Value |
|---|---|
| b₁ | 0 |
| b₂ | 1 |
| b₃ | 1 |
| b₄ | 0 |

In block 320, the user computing device 110 determines a confidence score for each decoded modulation symbol. In an example, the respective confidence score is determined within the process of decoding the one or more modulation symbols. The decoding of the one or more modulation symbols may be carried out in accordance with the teaching presented in U.S. Pat. No. 9,319,096. In an example, the confidence score reflects whether each modulation symbol is decoded correctly. In an example, the confidence score is an error probability. In an example, a confidence score that is equal to 1.0 indicates that the modulation symbol has been decoded correctly. In an example, a confidence score that is greater than a configured threshold but less than 1.0 may indicate that noise was present in the audio transmission, however the symbol is likely to have been decoded correctly. In an example, noise may be caused by speech harmonics, environmental noise, interference from other broadcasters, or other sources. In an example, a confidence score that is less than a configured threshold may indicate that the symbol was not decoded correctly and therefore contains an error. In an example, the configured threshold may be 0.3, 0.4, 0.5, or any other suitable threshold value.

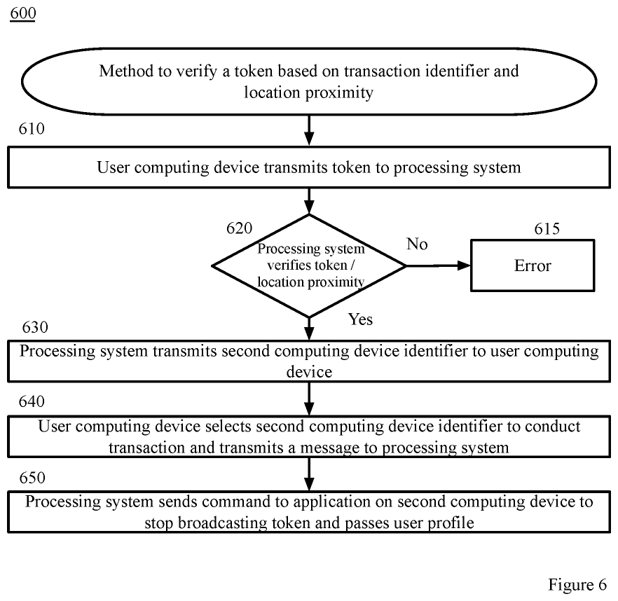

In block 330, a CRC is performed on the decoded modulation symbols d₁, . . . dₙ, . . . , d₆. In an example, to perform a CRC, a check value is calculated for the decoded modulation symbols. The calculated check value is compared to the received CRC. If the calculated check value matches the CRC, the decoded modulation symbols pass the CRC and the method 300 proceeds to block 335 wherein the token is accepted as received with integrity by user computing device 110. In an example, the token being accepted as received with integrity indicates that the modulation symbols pass the CRC check in block 330. If the token is accepted as received with integrity in block 335, the method proceeds to block 610 in FIG. 6.

Returning to block 330 in FIG. 3, if the decoded modulation symbols do not pass the CRC, the method proceeds to block 340. In block 340, the user computing device 110 determines the location of each symbol with a confidence score below the configured threshold, where there is at least one symbol with a confidence score below the configured threshold. In an example, the symbol may be a modulation symbol or a CRC check symbol. In an example, each determined location with a confidence score below the configured threshold contains a symbol error.

After determining the location each of symbol with a confidence score below the configured threshold, the method proceeds to block 350. In block 350, the user computing device 110 counts the number of symbol locations with a confidence score below the configured threshold, i.e., the number of locations containing a symbol error.

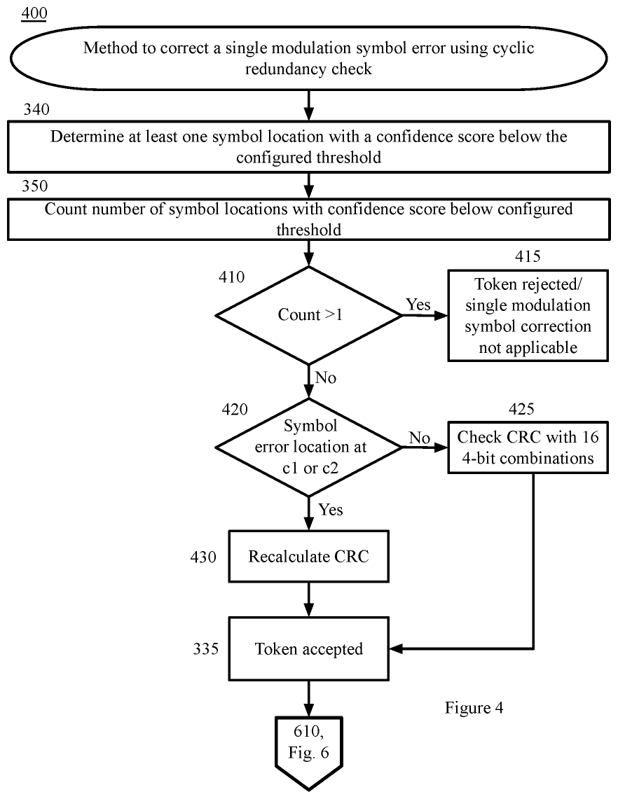

FIG. 4 is a block flow diagram depicting a method 400 to correct a single modulation symbol error using cyclic redundancy check, in accordance with certain example embodiments. The method 400 is described with reference to the components illustrated in FIG. 1.

The method 400 depicted in FIG. 4 begins at block 340 wherein the user computing device 110 locates each symbol with a confidence score below the configured threshold, and wherein there is at least one symbol with a confidence score below the configured threshold, as described in greater detail with respect to FIG. 3. In an example, each location with a confidence score below the configured threshold contains a symbol error. Method 400 proceeds to block 350, wherein the user computing device 110 counts the number of symbol locations with a confidence score below the configured threshold, as described in greater detail with respect to FIG. 3. In block 410, if the count of the number of symbol locations with a confidence score below the configured threshold from block 350 is greater than 1, the method proceeds to block 415. In block 415, the token cannot be corrected using single modulation symbol error correction and the token is rejected.

Returning to block 410, if the count of the number of symbol locations with a confidence score below the configured threshold from block 350 is not greater than 1 (i.e., the count is equal to 1) the method proceeds to block 420. In block 420, the user computing device 110 determines if the symbol error is located at one of the CRC check symbol locations, c₁ or c₂. If the symbol error is not located at one of the CRC check symbols, c₁ or c₂, the method proceeds to block 425.

In block 425, for a single symbol error location, there is one symbol and therefore four bits within which the error may be located. Each bit possesses one of two values, 0 or 1. The user computing device 110 cycles through each of the 16 possible combinations of 0 and 1 for each of the four bits (i.e., 1 of 16, 2 of 16, 3 of 16, etc.). After each cycle, the check value for the decoded modulation symbols is recalculated and compared to the received CRC. If the recalculated check value matches the received CRC, the combination passes the CRC check and the symbol error is corrected. If the recalculated check value does not match the received CRC, the symbol error is not corrected and the user computing device 110 continues to cycle through the remaining combinations. When a combination passes the CRC and the symbol error is therefore corrected, the method proceeds to block 335, wherein the token is accepted as received with integrity by the user computing device 110, as described in greater detail with respect to FIG. 3, and the method proceeds to block 610 in FIG. 6. The following table illustrates an example of correcting a single symbol error located at modulation symbol dₙ.

Example Single Symbol Error Correction
Location Modulation Symbol dₙ

| Bit | Decoded Bit | | | | |
|---|---|---|---|---|---|
| Designation | Value | Cycle 1/16 | Cycle 2/16 | . . . | Cycle n/16 |
| b₁ | 0 | 1 | 0 | | 1 |
| b₂ | 1 | 1 | 0 | | 0 |
| b₃ | 1 | 1 | 1 | | 0 |
| b₄ | 0 | 0 | 0 | | 1 |
| Passes CRC | No | No | No | | Yes |

Returning to block 420, if the symbol error is located at one of the CRC check symbol locations, c₁ or c₂, the method proceeds to block 430, wherein the CRC is recalculated. The method proceeds to block 335 wherein the token is accepted as received with integrity by user computing device 110, as described in greater detail with respect to FIG. 3, and the method proceeds to block 610 in FIG. 6.

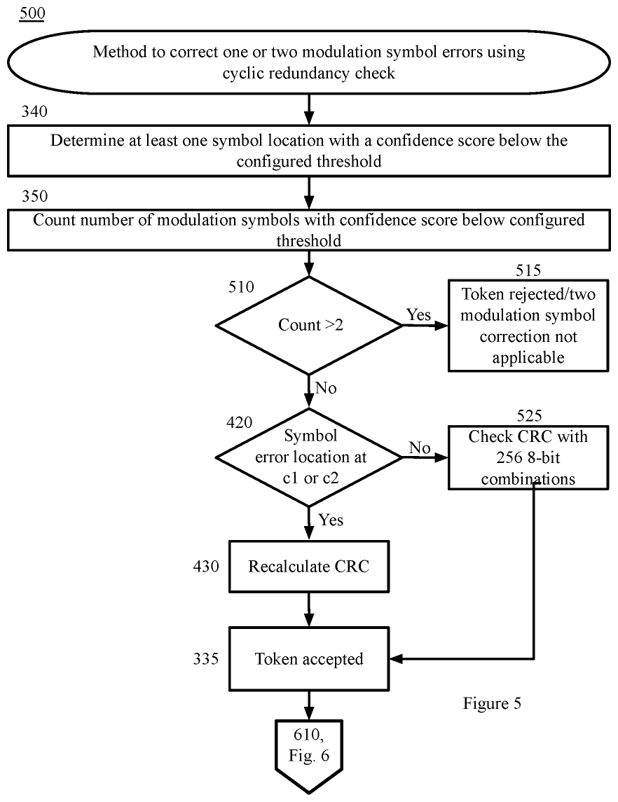

FIG. 5 is a block flow diagram depicting a method 500 to correct one or two modulation symbol errors using CRC, in accordance with certain example embodiments. The method 500 is described with reference to the components illustrated in FIG. 1.

The method 500 depicted in FIG. 5 begins at block 340 wherein the user computing device 110 locates each symbol with a confidence score below the configured threshold, and wherein there is at least one symbol with a confidence score below the configured threshold, as described in greater detail with respect to FIG. 3. In an example, each location with a confidence score below the configured threshold contains a symbol error. Method 500 proceeds to block 350 wherein the user computing device 110 counts the number of symbol locations with a confidence score below the configured threshold, as described in greater detail with respect to FIG. 3. In block 510, if the count of the number of symbol locations with a confidence score below the configured threshold from block 350 is greater than 2, the method proceeds to block 515. In block 515, the token cannot be corrected using one or two modulation symbol error correction and the token is rejected.

Returning to block 510, if the count of the number of symbol locations with a confidence score below the configured threshold from block 350 is not greater than 2 (i.e., equal to 1 or 2) the method proceeds to block 420. In block 420, the user computing device 110 determines if the symbol errors are located at the CRC check symbol locations, c₁ or c₂. If the symbol errors are not located at the CRC check symbols, c₁ or c₂, the method proceeds to block 525.

In block 525, for one or two symbol error locations, there are eight bits within which the error may be located. Each bit possesses one of two values, 0 or 1. The user computing device 110 cycles through each of the 256 possible combinations of 0 and 1 for each of the eight bits (i.e., 1 of 256, 2 of 256, 3 of 256, etc.). After each cycle, the check value for the decoded modulation symbols is recalculated and compared to the received CRC. If the recalculated check value matches the received CRC, the combination passes the CRC check and the symbol error is corrected. If the recalculated check value does not match the received CRC, the symbol error is not corrected and the user computing device 110 continues to cycle through the remaining combinations. When a combination passes the CRC and the symbol error is therefore corrected, the method proceeds to block 335, wherein the token is accepted as received with integrity by the user computing device 110, as described in greater detail with respect to FIG. 3, and the method proceeds to block 610 in FIG. 6.

Returning to block 420, if the symbol errors are located at either or both of the CRC check symbol locations, c₁ or c₂, the method proceeds to block 430, wherein the CRC is recalculated. The method proceeds to block 335, wherein the token is accepted as received with integrity by the user computing device 110, as described in greater detail with respect to FIG. 3, and the method proceeds to block 610 in FIG. 6.

FIG. 6 is a block flow diagram depicting a method 600 to verify a token based on a transaction identifier and location proximity, in accordance with certain example embodiments. The method 600 is described with reference to the components illustrated in FIG. 1.

The method 600 begins at block 610 where the token is transmitted to the processing system 140 via the network 120.

In block 620, the processing system 140 verifies the token by matching the transaction identifier contained in the token transmitted by the user computing device 110 to the transaction identifier transmitted to the processing system 140 by the second computing device 130 in block 220 of FIG. 2. The processing system 140 compares the location of user computing device 110 to the location of the user associated with the token to verify that the user computing device 110 is located within a configured threshold distance from the user associated with the token. In an example, the user associated with the token is the second computing device 130. If the processing system 140 cannot verify the token or cannot verify that the user computing device 110 is located within a configured threshold distance from user associated with the token, the method proceeds to block 615 indicating that an error has occurred. If the processing system 140 can verify the token and verify that the user computing device 110 is located within a configured threshold distance from the user associated with the token, the method proceeds to block 630.

In block 630, the processing system 140 transmits via network 120 the second computing device 130 identifier to the user computing device 110. Continuing to block 640, the user computing device 110 selects the received second computing device 130 identifier for use in the transaction and transmits a message to the processing system 140 that the second computing device 130 identifier has been received.

In block 650, the processing system 140 sends a command to application 133 on the second computing device 130 to stop the audio broadcast of the token and passes the user 101 profile.

### Other Examples Embodiments

FIG. 7 depicts a computing machine 2000 and a module 2050 in accordance with certain example embodiments. The computing machine 2000 may correspond to any of the various computers, servers, mobile devices, embedded systems, or computing systems presented herein. The module 2050 may comprise one or more hardware or software elements configured to facilitate the computing machine 2000 in performing the various methods and processing functions presented herein. The computing machine 2000 may include various internal or attached components such as a processor 2010, system bus 2020, system memory 2030, storage media 2040, input/output interface 2060, and a network interface 2070 for communicating with a network 2080.

The computing machine 2000 may be implemented as a conventional computer system, an embedded controller, a laptop, a server, a mobile device, a smartphone, a set-top box, a kiosk, a router or other network node, a vehicular information system, one or more processors associated with a television, a customized machine, any other hardware platform, or any combination or multiplicity thereof. The computing machine 2000 may be a distributed system configured to function using multiple computing machines interconnected via a data network or bus system.

The processor 2010 may be configured to execute code or instructions to perform the operations and functionality described herein, manage request flow and address mappings, and to perform calculations and generate commands. The processor 2010 may be configured to monitor and control the operation of the components in the computing machine 2000. The processor 2010 may be a general purpose processor, a processor core, a multiprocessor, a reconfigurable processor, a microcontroller, a digital signal processor (“DSP”), an application specific integrated circuit (“ASIC”), a graphics processing unit (“GPU”), a field programmable gate array (“FPGA”), a programmable logic device (“PLD”), a controller, a state machine, gated logic, discrete hardware components, any other processing unit, or any combination or multiplicity thereof. The processor 2010 may be a single processing unit, multiple processing units, a single processing core, multiple processing cores, special purpose processing cores, co-processors, or any combination thereof. According to certain embodiments, the processor 2010 along with other components of the computing machine 2000 may be a virtualized computing machine executing within one or more other computing machines.

The system memory 2030 may include non-volatile memories such as read-only memory (“ROM”), programmable read-only memory (“PROM”), erasable programmable read-only memory (“EPROM”), flash memory, or any other device capable of storing program instructions or data with or without applied power. The system memory 2030 may also include volatile memories such as random access memory (“RAM”), static random access memory (“SRAM”), dynamic random access memory (“DRAM”), and synchronous dynamic random access memory (“SDRAM”). Other types of RAM also may be used to implement the system memory 2030. The system memory 2030 may be implemented using a single memory module or multiple memory modules. While the system memory 2030 is depicted as being part of the computing machine 2000, one skilled in the art will recognize that the system memory 2030 may be separate from the computing machine 2000 without departing from the scope of the subject technology. It should also be appreciated that the system memory 2030 may include, or operate in conjunction with, a non-volatile storage device such as the storage media 2040.

The storage media 2040 may include a hard disk, a floppy disk, a compact disc read only memory (“CD-ROM”), a digital versatile disc (“DVD”), a Blu-ray disc, a magnetic tape, a flash memory, other non-volatile memory device, a solid state drive (“SSD”), any magnetic storage device, any optical storage device, any electrical storage device, any semiconductor storage device, any physical-based storage device, any other data storage device, or any combination or multiplicity thereof. The storage media 2040 may store one or more operating systems, application programs and program modules such as module 2050, data, or any other information. The storage media 2040 may be part of, or connected to, the computing machine 2000. The storage media 2040 may also be part of one or more other computing machines that are in communication with the computing machine 2000 such as servers, database servers, cloud storage, network attached storage, and so forth.

The module 2050 may comprise one or more hardware or software elements configured to facilitate the computing machine 2000 with performing the various methods and processing functions presented herein. The module 2050 may include one or more sequences of instructions stored as software or firmware in association with the system memory 2030, the storage media 2040, or both. The storage media 2040 may therefore represent examples of machine or computer readable media on which instructions or code may be stored for execution by the processor 2010. Machine or computer readable media may generally refer to any medium or media used to provide instructions to the processor 2010. Such machine or computer readable media associated with the module 2050 may comprise a computer software product. It should be appreciated that a computer software product comprising the module 2050 may also be associated with one or more processes or methods for delivering the module 2050 to the computing machine 2000 via the network 2080, any signal-bearing medium, or any other communication or delivery technology. The module 2050 may also comprise hardware circuits or information for configuring hardware circuits such as microcode or configuration information for an FPGA or other PLD.

The input/output (“I/O”) interface 2060 may be configured to couple to one or more external devices, to receive data from the one or more external devices, and to send data to the one or more external devices. Such external devices along with the various internal devices may also be known as peripheral devices. The I/O interface 2060 may include both electrical and physical connections for operably coupling the various peripheral devices to the computing machine 2000 or the processor 2010. The I/O interface 2060 may be configured to communicate data, addresses, and control signals between the peripheral devices, the computing machine 2000, or the processor 2010. The I/O interface 2060 may be configured to implement any standard interface, such as small computer system interface (“SCSI”), serial-attached SCSI (“SAS”), fiber channel, peripheral component interconnect (“PCP”), PCI express (PCIe), serial bus, parallel bus, advanced technology attached (“ATA”), serial ATA (“SATA”), universal serial bus (“USB”), Thunderbolt, FireWire, various video buses, and the like. The I/O interface 2060 may be configured to implement only one interface or bus technology. Alternatively, the I/O interface 2060 may be configured to implement multiple interfaces or bus technologies. The I/O interface 2060 may be configured as part of, all of, or to operate in conjunction with, the system bus 2020. The I/O interface 2060 may include one or more buffers for buffering transmissions between one or more external devices, internal devices, the computing machine 2000, or the processor 2010.

The I/O interface 2060 may couple the computing machine 2000 to various input devices including mice, touch-screens, scanners, electronic digitizers, sensors, receivers, touchpads, trackballs, cameras, microphones, keyboards, any other pointing devices, or any combinations thereof. The I/O interface 2060 may couple the computing machine 2000 to various output devices including video displays, speakers, printers, projectors, tactile feedback devices, automation control, robotic components, actuators, motors, fans, solenoids, valves, pumps, transmitters, signal emitters, lights, and so forth.

The computing machine 2000 may operate in a networked environment using logical connections through the network interface 2070 to one or more other systems or computing machines across the network 2080. The network 2080 may include wide area networks (WAN), local area networks (LAN), intranets, the Internet, wireless access networks, wired networks, mobile networks, telephone networks, optical networks, or combinations thereof. The network 2080 may be packet switched, circuit switched, of any topology, and may use any communication protocol. Communication links within the network 2080 may involve various digital or an analog communication media such as fiber optic cables, free-space optics, waveguides, electrical conductors, wireless links, antennas, radio-frequency communications, and so forth.

The processor 2010 may be connected to the other elements of the computing machine 2000 or the various peripherals discussed herein through the system bus 2020. It should be appreciated that the system bus 2020 may be within the processor 2010, outside the processor 2010, or both. According to certain example embodiments, any of the processor 2010, the other elements of the computing machine 2000, or the various peripherals discussed herein may be integrated into a single device such as a system on chip (“SOC”), system on package (“SOP”), or ASIC device.

In situations in which the systems discussed here collect personal information about users, or may make use of personal information, the users may be provided with an opportunity or option to control whether programs or features collect user information (e.g., information about a user's social network, social actions or activities, profession, a user's preferences, or a user's current location), or to control whether and/or how to receive content from the content server that may be more relevant to the user. In addition, certain data may be treated in one or more ways before it is stored or used, so that personally identifiable information is removed. For example, a user's identity may be treated so that no personally identifiable information can be determined for the user, or a user's geographic location may be generalized where location information is obtained (such as to a city, ZIP code, or state level), so that a particular location of a user cannot be determined. Thus, the user may have control over how information is collected about the user and used by a content server.

Embodiments may comprise a computer program that embodies the functions described and illustrated herein, wherein the computer program is implemented in a computer system that comprises instructions stored in a machine-readable medium and a processor that executes the instructions. However, it should be apparent that there could be many different ways of implementing embodiments in computer programming, and the embodiments should not be construed as limited to any one set of computer program instructions. Further, a skilled programmer would be able to write such a computer program to implement an embodiment of the disclosed embodiments based on the appended flow charts and associated description in the application text. Therefore, disclosure of a particular set of program code instructions is not considered necessary for an adequate understanding of how to make and use embodiments. Further, those skilled in the art will appreciate that one or more aspects of embodiments described herein may be performed by hardware, software, or a combination thereof, as may be embodied in one or more computing systems. Moreover, any reference to an act being performed by a computer should not be construed as being performed by a single computer as more than one computer may perform the act.

The examples described herein can be used with computer hardware and software that perform the methods and processing functions described herein. The systems, methods, and procedures described herein can be embodied in a programmable computer, computer-executable software, or digital circuitry. The software can be stored on computer-readable media. For example, computer-readable media can include a floppy disk, RAM, ROM, hard disk, removable media, flash memory, memory stick, optical media, magneto-optical media, CD-ROM, etc. Digital circuitry can include integrated circuits, gate arrays, building block logic, field programmable gate arrays (FPGA), etc.

The example systems, methods, and acts described in the embodiments presented previously are illustrative, and, in alternative embodiments, certain acts can be performed in a different order, in parallel with one another, omitted entirely, and/or combined between different examples, and/or certain additional acts can be performed, without departing from the scope and spirit of various embodiments. Accordingly, such alternative embodiments are included in the scope of the following claims, which are to be accorded the broadest interpretation so as to encompass such alternate embodiments.

Although specific embodiments have been described above in detail, the description is merely for purposes of illustration. It should be appreciated, therefore, that many aspects described above are not intended as required or essential elements unless explicitly stated otherwise. Modifications of, and equivalent components or acts corresponding to, the disclosed aspects of the examples, in addition to those described above, can be made by a person of ordinary skill in the art, having the benefit of the present disclosure, without departing from the spirit and scope of embodiments defined in the following claims, the scope of which is to be accorded the broadest interpretation so as to encompass such modifications and equivalent structures.

1. A computer-implemented method to correct a single modulation symbol error received during audio pairing of computing devices, comprising, by a computing device:
receiving an audio transmission, wherein the audio transmission comprises audio token data and a check value, and wherein the audio token data comprises one or more modulation symbols;
decoding the one or more modulation symbols;
calculating an audio token data check value;
determining that the calculated audio token data check value does not match the received check value;
determining an error probability for each decoded modulation symbol;
comparing the error probability for each decoded modulation symbol with a threshold;
determining that the audio token data has a single symbol error, wherein a symbol error occurs at a decoded modulation symbol location where the error probability is less than the threshold;
modifying the decoded modulation symbol at the decoded modulation symbol location comprised of the single symbol error;
recalculating the audio token check value;
comparing the recalculated audio token check value with the received check value; and
accepting the audio token data when the recalculated audio token check value matches the received check value.

2. The computer-implemented method of claim 1, wherein the error probability is a confidence score.

3. The computer-implemented method of claim 1, wherein the threshold is 0.5.

4. The computer-implemented method of claim 1, wherein the audio token data comprises six modulation symbols, wherein each modulation symbol comprises four bits, and wherein each bit is comprised of a value of 0 or 1.

5. The computer-implemented method of claim 1, wherein decoding the one or more modulation symbols comprises translating the one or more modulation symbols into bits, wherein each bit has a decoded value of 0 or 1.

6. The computer-implemented method of claim 1, wherein modifying the decoded modulation symbol at the decoded modulation symbol location comprised of the single symbol error further comprises replacing a decoded value of a bit with a modified bit value, wherein when the decoded value of the bit is 0, the modified bit value is 1, and wherein when the decoded value of the bit is 1, the modified bit value is 0.

7. The computer-implemented method of claim 1, wherein the check value is a cyclic redundancy check value.

8. The computer-implemented method of claim 1, wherein the check value is comprised of two check symbols, wherein each check symbol is comprised of four bits, and wherein each bit is comprised of a value of 0 or 1.

9. The computer-implemented method of claim 2, wherein the respective confidence score is determined within the process of decoding the one or more modulations symbols.

10. One or more non-transitory computer-readable media that store instructions that when executed by one or more processors cause the one or more processors to perform operations, the operations comprising:
receive an audio transmission, wherein the audio transmission comprises audio token data and a check value, and wherein the audio token data comprises one or more modulation symbols;
decode the one or more modulation symbols;
calculate an audio token data check value;
determine that the calculated audio token data check value does not match the received check value;
determine an error probability for each decoded modulation symbol;
compare the error probability for each decoded modulation symbol with a threshold;
determine that the audio token data has a single symbol error, wherein a symbol error occurs at a decoded modulation symbol location where the error probability is less than the threshold;
modify the decoded modulation symbol at the decoded modulation symbol location comprised of the single symbol error;
recalculate the audio token check value;
compare the recalculated audio token check value with the received check value; and
accept the audio token data when the recalculated audio token check value matches the received check value.

11. The one or more non-transitory media of claim 10, wherein the error probability is a confidence score.

12. The one or more non-transitory media of claim 10, wherein the threshold is 0.5.

13. The one or more non-transitory media of claim 10, wherein the audio token data comprises six modulation symbols, wherein each modulation symbol comprises four bits, wherein the check value is comprised of two check symbols, wherein each check symbol is comprised of four bits, and wherein each bit is comprised of a value of 0 or 1.

14. The one or more non-transitory media of claim 10, wherein decoding the one or more modulation symbols comprises translating the one or more modulation symbols into bits, wherein each bit has a decoded value of 0 or 1.

15. The one or more non-transitory media of claim 10, wherein modifying the decoded modulation symbol at the decoded modulation symbol location comprised of the single symbol error further comprises replacing a decoded value of a bit with a modified bit value, wherein when the decoded value of the bit is 0, the modified bit value is 1, and wherein when the decoded value of the bit is 1, the modified bit value is 0.

16. The one or more non-transitory media of claim 10, wherein the check value is a cyclic redundancy check value.

17. The one or more non-transitory media of claim 11, wherein the respective confidence score is determined within the process of decoding the one or more modulations symbols.

18. A system to correct a single modulation symbol error received during audio pairing of computing devices, comprising:
one or more processors;
one or more non-transitory computer-readable media that store instructions that when executed by the one or more processors cause the one or more processors to perform operations, the operations comprising:
receiving an audio transmission, wherein the audio transmission comprises audio token data and a check value, and wherein the audio token data comprises one or more modulation symbols;
decoding the one or more modulation symbols;
calculating an audio token data check value;
determining that the calculated audio token data check value does not match the received check value;
determining an error probability for each decoded modulation symbol;
comparing the error probability for each decoded modulation symbol with a threshold;
determining that the audio token data has a single symbol error, wherein a symbol error occurs at a decoded modulation symbol location where the error probability is less than the threshold;
modifying the decoded modulation symbol at the decoded modulation symbol location comprised of the single symbol error;
recalculating the audio token check value;
comparing the recalculated audio token check value with the received check value; and
accepting the audio token data when the recalculated audio token check value matches the received check value.

19. The system of claim 18, wherein decoding the one or more modulation symbols comprises translating the one or more modulation symbols into bits, wherein each bit has a decoded value of 0 or 1.

20. The system of claim 18, wherein modifying the decoded modulation symbol at the decoded modulation symbol location comprised of the single symbol error further comprises replacing a decoded value of a bit with a modified bit value, wherein when the decoded value of the bit is 0, the modified bit value is 1, and wherein when the decoded value of the bit is 1, the modified bit value is 0.
